(19) United States
(12) Patent Application Publication
(10) Pub. No.: US 2023/0215785 A1
(43) Pub. Date: Jul. 6, 2023

(54) VERTICAL TYPE MULTI-CHIP DEVICE

(71) Applicant: HARVATEK CORPORATION, Hsinchu City (TW)

(72) Inventors: CHIN-JUI LIANG, Hsinchu City (TW); Hui-Yen Huang, HSINCHU CITY (TW); FENG-HUI CHUANG, New Taipei City (TW); PING-LUNG WANG, HSINCHU CITY (TW)

(21) Appl. No.: 17/688,965

(22) Filed: Mar. 8, 2022

(30) Foreign Application Priority Data
Dec. 30, 2021 (TW) 110149606

(51) Int. Cl. H01L 23/495; H01L 21/48; H01L 25/065

(52) U.S. Cl. CPC H01L 23/49537; H01L 23/49575; H01L 21/4825; H01L 25/0657; H01L 2225/06555

(57) ABSTRACT

A vertical type multi-chip device includes a base structure, an intermediate layer, a first functional chip, and a second functional chip. The intermediate layer is disposed on the base structure and has a first signal transmission path and a second signal transmission path. The first functional chip is embedded in the intermediate layer and electrically connected to the base structure. The second functional chip is disposed on the intermediate layer and configured to be electrically connected to the first functional chip via the first signal transmission path and to the base structure via the second signal transmission path.

### CROSS-REFERENCE TO RELATED PATENT APPLICATION

This application claims the benefit of priority to Taiwan Patent Application No. 110149606, filed on Dec. 30, 2021. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a semiconductor device, and more particularly to a vertical type multi-chip device, which is suitable for use in handheld and miniature electronic products such as digital cameras, smartphones, tablets, and satellite navigation systems.

### BACKGROUND OF THE DISCLOSURE

In the information society of today, electronic products on the market are required to have high performance, multiple functions, and a thin and lightweight design. Therefore, many package designs for integrating chips of the same or different types into a single package such as multi-chip modules (MCM) and system-in-package (SIP) have been developed. However, such package designs need to be capable of accommodating complex layouts for electrical connections (e.g., interior and exterior electrical connections) within limited space, which is highly reliant upon superior manufacturing processes and is difficult to be achieved by the average process.

A lead frame is one of the commonly used packaging substrates for multi-chip integration. As chips continue to progress toward miniaturization, the structure of the lead frame must be changed accordingly to provide a higher density, a finer structure, and a greater quantity of leads. Once part of the lead frame is improperly arranged, the lead frame may cause a short circuit and may not be able to provide sufficient supporting strength. Furthermore, while a vertical stacking of chips is one of the most effective structures for multi-chip integration, in which through silicon vias (TSV) are used to provide vertical interconnections between the chips, the making of through-silicon vias requires expensive processing equipment and a large number of consumables, such that costs concerns have become one of the foremost considerations when seeking improvement in the relevant industry.

### SUMMARY OF THE DISCLOSURE

The present disclosure focuses on realizing a multi-chip module package with no wiring lines and through silicon vias by virtue of one or more intermediate layers used for vertical integration of chips in a 3D space and providing signal transmission paths between the chips at an upper position and a base structure.

In one aspect, the present disclosure provides a vertical type multi-chip device, which includes a base structure, an intermediate layer, a first functional chip, and a second functional chip. The intermediate layer is disposed on the base structure and has a first signal transmission path and a second signal transmission path. The first functional chip is embedded in the intermediate layer and electrically connected to the base structure. The second functional chip is disposed on the intermediate layer and configured to be electrically connected to the first functional chip via the first signal transmission path and to the base structure via the second signal transmission path.

In certain embodiments, the intermediate layer has an inner side area and an outer side area. The inner side area has a first conductive structure arranged therein, and the outer side area has a second conductive structure arranged therein. The first conductive structure is configured to provide the first signal transmission path, and the second conductive structure is configured to provide the second signal transmission path.

In certain embodiments, the first conductive structure is a line redistribution structure, and the second conductive structure includes a plurality of conductive vias.

In certain embodiments, the base structure includes a first conductive portion and a plurality of second conductive portions arranged adjacent to and at a periphery of the first conductive portion. The first functional chip is in electrical connection with both the first conductive portion and the second conductive portions. The second functional chip is in electrical connection with the second conductive portions via the second signal transmission path of the intermediate layer.

In certain embodiments, the first conductive portion is located in an orthogonal projection area of the first functional chip on the base structure, and the second conductive portions are arranged in a radial distribution around the first conductive portion and with the first conductive portion as a center.

In certain embodiments, the first conductive portion is a single lead or multi-lead electrode, and the second conductive portions are each a lead.

In certain embodiments, the base structure has a central area and a peripheral area outside the central area. The first conductive portion is arranged in the central area, and the second conductive portions are arranged in the peripheral area outside.

In certain embodiments, the vertical type multi-chip device further includes a plurality of supporting portions, each of which has a first end immovably fixed to the peripheral area and a second end connected to the first conductive portion.

In certain embodiments, the first conductive portion is a single lead or multi-lead electrode. The second conductive portions are each a lead. The supporting portions are each a connecting rod.

In certain embodiments, the first conductive portion includes a plurality of conductive bodies separated from each other and immovably fixed to the second end of at least one of the supporting portions.

In certain embodiments, the first conductive portion has a plurality of hollow structures.

In certain embodiments, the peripheral area of the base structure has a plurality of corner positions, and the first ends of the supporting portions are respectively and immovably fixed to the corner positions.

In certain embodiments, the vertical type multi-chip device further includes a protective layer that isolates the intermediate layer, the first functional layer, and the second functional layer from an outside environment.

In certain embodiments, the vertical type multi-chip device further includes a metal shielding layer disposed on the protective layer.

In certain embodiments, the protective layer has a lateral surface surrounding the intermediate layer, the first functional layer, and the second functional layer and an upper surface perpendicular to and connected to the lateral surface. The metal shielding layer covers the lateral surface and the upper surface.

In certain embodiments, the vertical type multi-chip device further includes a heat dissipating member that is disposed between the second functional chip and the metal shielding layer.

One of the beneficial effects of the subject matter provided by the present disclosure is that, in the vertical type multi-chip device of the present disclosure, by virtue of “the first functional chip is embedded in the intermediate layer and electrically connected to the base structure, and the second functional chip is disposed on the intermediate layer and configured to be electrically connected to the first functional chip via the first signal transmission path and to the base structure via the second signal transmission path,” a closer interconnection in a vertical direction between chips and between chips and a base structure can be achieved based on general process capability, and no wiring lines and through silicon vias are used in an entire structure. Furthermore, the vertical type multi-chip device of the present disclosure has the advantages of higher flexibility of use, a smaller volume, and a higher integration density.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view a vertical type multi-chip device according to a first embodiment of the present disclosure;

FIG. 2 is a top view of a base structure of the vertical type multi-chip device according to the first embodiment of the present disclosure;

FIG. 3 is a top view of a portion of the vertical type multi-chip device according to the first embodiment of the present disclosure;

FIG. 4 is a schematic view of a vertical type multi-chip device according to a second embodiment of the present disclosure;

FIG. 5 is a planar view of a vertical type multi-chip device according to a third embodiment of the present disclosure; and

FIG. 6 is another planar view of the vertical type multi-chip device according to the third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

[First Embodiment]

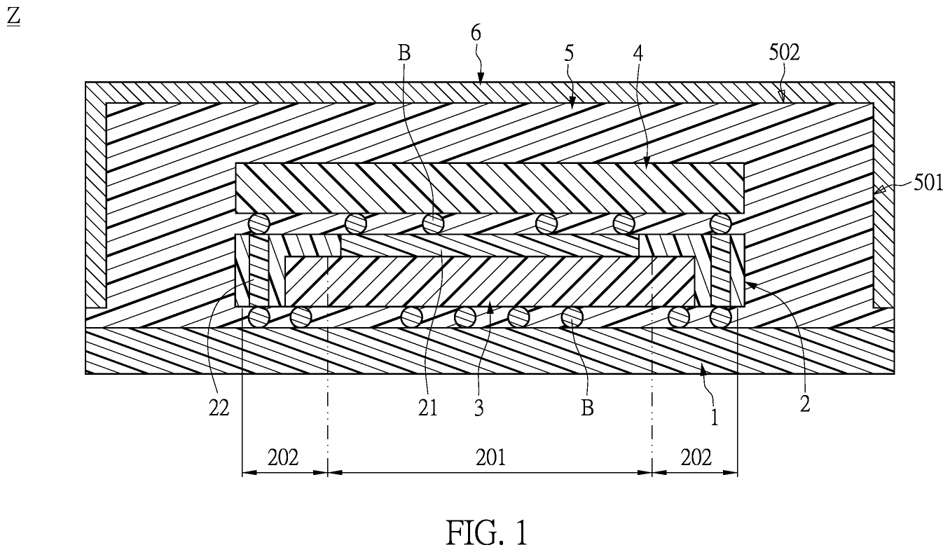

Referring to FIG. 1, a vertical type multi-chip device Z according to a first embodiment of the present disclosure is shown, which mainly includes a base structure 1, an intermediate layer 2, a first functional chip 3, and a second functional chip 4. The intermediate layer 2 is disposed on the base structure 1 and has a first signal transmission path and a second signal transmission path. The first functional chip 3 is embedded in the intermediate layer 2 and electrically connected to the base structure 1. The second functional chip 4 is disposed on the intermediate layer 2 and configured to be electrically connected to the first functional chip 3 via the first signal transmission path and to the base structure 1 via the second signal transmission path.

In use, the base structure 1 can provide power or signal transmission paths extending outwards from the first functional chip 3 and the second functional chip 4, and the first functional chip 3 and the second functional chip 4 can be in signal communication with each other via the intermediate layer 2. It is worth mentioning that, in the present embodiment, a dual chip device is used as an example to describe the design concept of the present disclosure, but the present disclosure is not limited thereto. In other words, any device with more than two chips which is completed by using the design concept of the present disclosure (i.e., using one or more intermediate layers to achieve a closer chip-to-chip or chip-to-base structure interconnection in a vertical direction should also be within the scope of the present disclosure.

In the present embodiment, the base structure 1 can be a lead frame or a package substrate that includes a first conductive portion 11 and a plurality of second conductive portions 12 arranged adjacent to and at a periphery of the first conductive portion 11. The first conductive portion 11 can serve as a common ground contact or at least one other common electrical contact, and can provide support and positioning for the first functional chip 3 and the second functional chip 4. The second conductive portions 12 can each serve as a signal transmission bridge between a chip and an external device (e.g., a printed circuit board). The first functional chip 3 is in electrical connection with both the first conductive portion 11 and the second conductive portions 12, and the second functional chip 4 is in electrical connection with the second conductive portions 12 via the second signal transmission path of the intermediate layer 2.

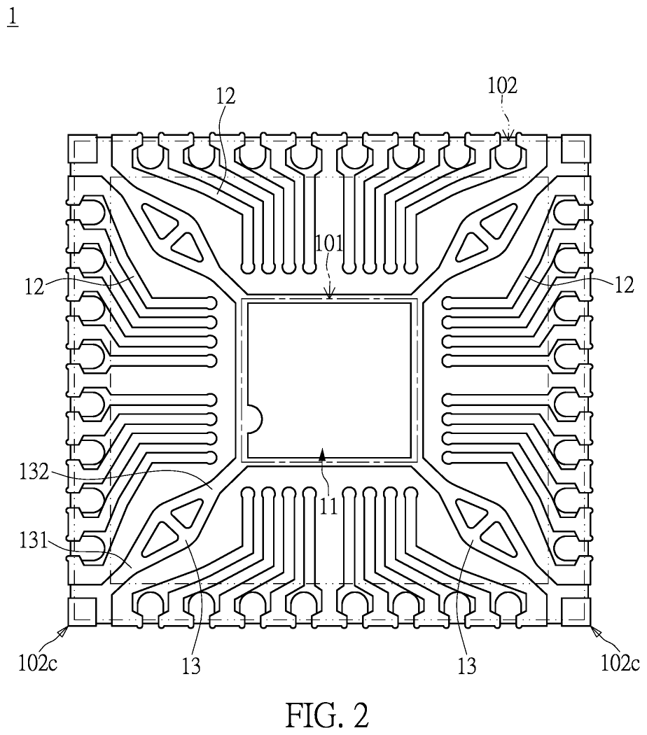

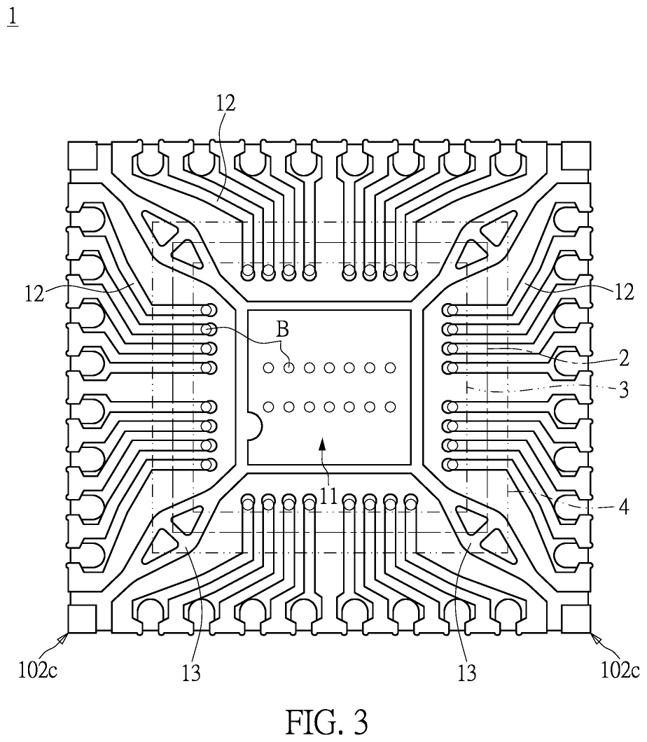

Reference is made to FIG. 2 and FIG. 3, which show a special layout of the vertical type multi-chip device Z. More specifically, the base structure 1 has a central area 101 and a peripheral area 102 outside the central area 101. The peripheral area 102 is arranged around the central area 101 in the present embodiment, but is not limited thereto. The first conductive portion 11 is arranged in the central area 101, and the second conductive portions 12 are arranged in the peripheral area 102. The first conductive portion 11 is a single lead or multi-lead electrode, and the second conductive portions 12 are each a lead. However, such examples are not intended to limit to the present disclosure. In consideration of spatial layout requirements, the first conductive portion 11 is located in an orthogonal projection area of the first functional chip 3 on the base structure 1, and the first functional chip 3 is located in an orthogonal projection area of the second functional chip 4 on the base structure 1. Furthermore, the second conductive portions 12 are arranged in a radial distribution around the first conductive portion 11 and with the first conductive portion 11 as a center, and a number of the second conductive portions 12 can have a bent portion.

In order to increase the support of the first conductive portion 11, the base structure 1 can further include a plurality of supporting portions 13 each having a first end 131 immovably fixed to the peripheral area 102 and a second end 132 connected to the first conductive portion 11. In practice, the peripheral area 102 of the base structure 1 can have a plurality of corner positions 102c. For example, FIG. 2 shows that the base structure 1 has a rectangular contour and four corner positions 102c. The first ends 131 of the supporting portions 13 are respectively and immovably fixed to the corner positions 102c. In the present disclosure, the supporting portions 13 are not particularly limited in structure as long as they can provide sufficient force and do not interfere with the spatial arrangement of the second conductive portions 12.

In practice, the first conductive portion 11 can be a single lead or multi-lead electrode. The second conductive portions 12 can each be a lead. The supporting portions 13 can each be a connecting rod. However, such examples are not intended to limit to the present disclosure.

The intermediate layer 2 is mainly composed of an insulating layer and includes a first conductive structure 21 and a second conductive structure 22. The first conductive structure 21 is configured to provide the first signal transmission path, and the second conductive structure 22 is configured to provide the second signal transmission path. More specifically, the first conductive structure 21 is disposed in an inner side area 201 of the intermediate layer 2 and configured to provide the first signal transmission path. The second conductive structure 22 is disposed in an outer side area 202 of the intermediate layer 2 and configured to provide the second signal transmission path. The first conductive structure 21 is a line redistribution structure, and the second conductive structure 22 includes a plurality of conductive vias, but the present disclosure is not limited thereto.

The first functional chip 3 can be respectively and electrically connected to the first conductive portion 11 and the second conductive portions 12 of the base structure 1 via a plurality of conductive bumps B. The second functional chip 4 can be respectively and electrically connected to the first conductive structure 21 and the second conductive structure 22 of the intermediate layer 2 via a plurality of conductive bumps B. The conductive bumps B can be solder balls, but are not limited thereto. Therefore, the first functional chip 3 and the second functional chip 4 can work with the base structure 1 to realize one or more main functions of an applied electronic product. It is worth mentioning that only a portion of the conductive bumps B are shown in FIG. 1 and FIGS. 3 to 6 so as to prevent the lines in FIG. 1 and FIGS. 3 to 6 from becoming more complicated and confusing.

Specific examples of the first functional chip 3 and the second functional chip 4 include NOR Flash, NAND Flash, DRAM, low power SRAM, pseudo SRAM, power IC, MCU, and CPU chips. However, such examples are not intended to limit to the present disclosure. Moreover, other electronic components such as a capacitor and an inductor can be included in addition to the first functional chip 3 and the second functional chip 4.

As shown in FIG. 1, the vertical type multi-chip device Z can further include a protective layer 5 to isolate the intermediate layer 2, the first functional chip 3, and the second functional chip 4 from an outside environment, thereby reducing negative impacts caused by environmental factors (e.g., humidity) and preventing the first functional chip 3 and the second functional chip 4 from being physically damaged. More specifically, the protective layer 5 can completely cover the intermediate layer 2, the first functional chip 3, and the second functional chip 4. The protective layer 5 has a lateral surface 501 surrounding the intermediate layer 2, the first functional chip 3, and the second functional chip 4 and an upper surface 502 perpendicular to and connected to the lateral surface 501. In practice, the protective layer 5 can be formed from a molding compound including epoxy resin or silicone, and it can further cover a portion or the entirety of the base structure 1, but the present disclosure is not limited thereto.

The vertical type multi-chip device Z can further include a metal shielding layer 6 disposed on the protective layer 5, thereby preventing the first functional chip 3 and the second functional chip 4 from being subjected to electromagnetic interference. In practice, the metal shielding layer 6 can cover the lateral surface 501 and the upper surface 502 of the protective layer 5, but the present is not limited thereto.

[Second Embodiment]

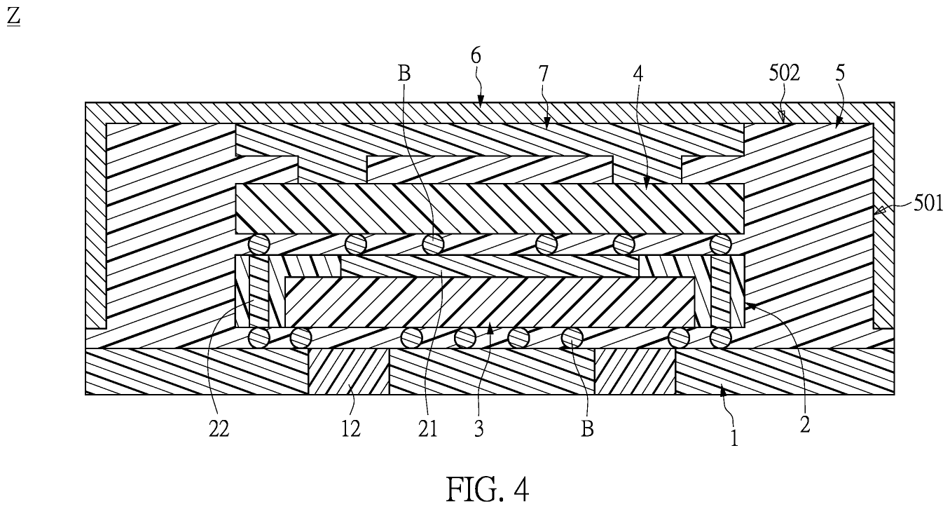

Referring to FIG. 4, a second embodiment of the present disclosure provides a vertical type multi-chip device. As show in FIG. 4, the vertical type multi-chip device Z further includes a heat dissipating member 7, in addition to a base structure 1, an intermediate layer 2, a first functional chip 3, a second functional chip 4, a protective layer 5, and a metal shielding layer 6 illustrated in the first embodiment.

In the present embodiment, the intermediate layer 2 is disposed on the base structure 1 and has a first signal transmission path and a second signal transmission path. The first functional chip 3 is embedded in the intermediate layer 2 and electrically connected to the base structure 1. The second functional chip 4 is disposed on the intermediate layer 2 and configured to be electrically connected to the first functional chip 3 via the first signal transmission path and to the base structure 1 via the second signal transmission path. The protective layer 5 isolates the intermediate layer 2, the first functional chip 3, and the second functional chip 4 from an outside environment. The metal shielding layer 6 is disposed on the protective layer 5. The heat dissipating member 7 is disposed between the second functional chip 4 and the metal shielding layer 6.

In practice, one portion of the heat dissipating member 7 is in contact with the second functional chip 4, and another one portion of the heat dissipating member 7 is in contact with the metal shielding layer 6. The heat dissipating member 7 can be, but is not limited to being, formed from one of the following metals and their alloys: gold, silver, copper, aluminum, tin and nickel. Therefore, heat generated by the first functional chip 3 and the second functional chip 4 can be quickly dissipated to the outside through the heat dissipating member 7. In the present disclosure, the heat dissipating member 7 is not particularly limited in structure as long as it can provide an effective heat dissipation effect.

The relevant technical details mentioned in the first embodiment are still valid in the present embodiment and will not be repeated here for the sake of brevity. Similarly, the technical details mentioned in the present embodiment can also be applied in the first embodiment.

[Third Embodiment]

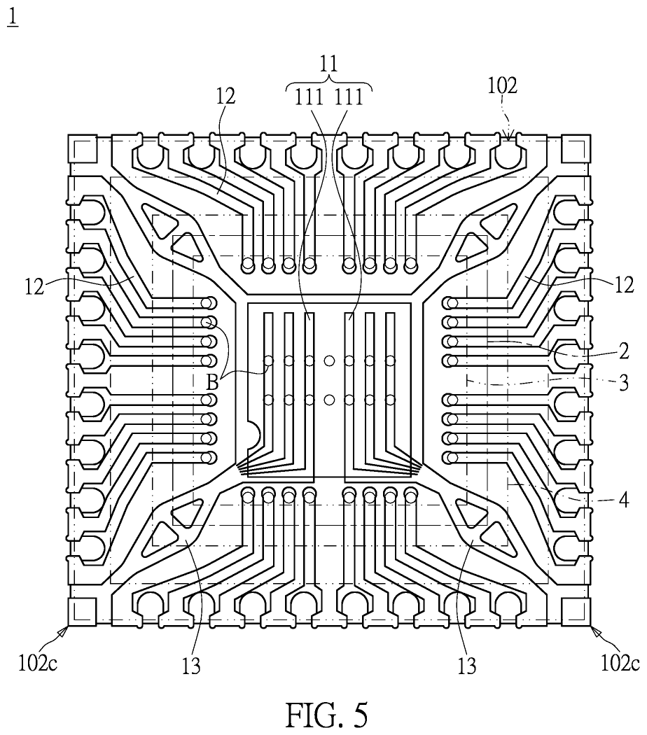

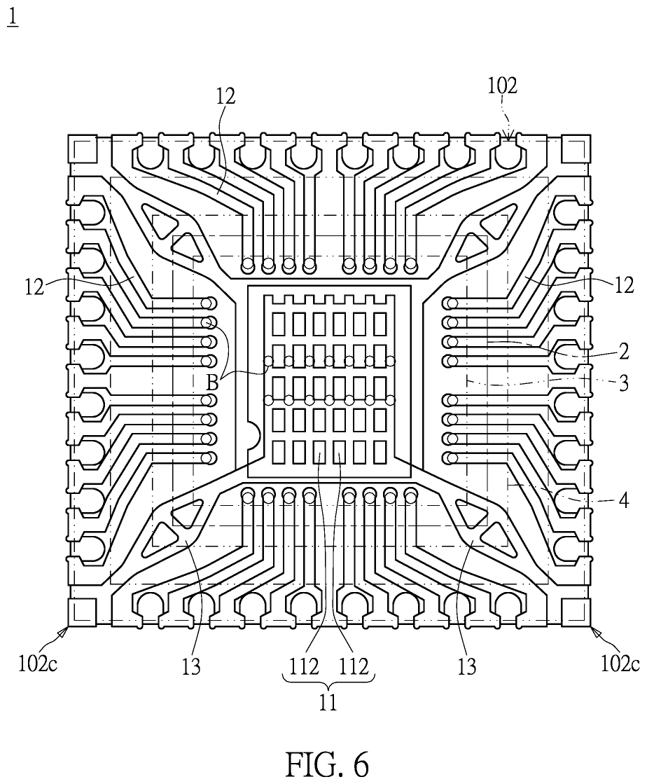

Referring to FIG. 5 and FIG. 6, a third embodiment of the present disclosure provides a planar multi-chip device Z. As show in FIG. 5 and FIG. 6, a first conductive portion 11 of a base structure 1 can be patterned. More specifically, the first conductive portion 11 can include a plurality of conductive bodies 111 (e.g., conductive pads as shown in FIG. 5) separated from each other that are immovably fixed to a second end 132 of at least one supporting portion 13. In practice, the conductive bodies 111 can be distributed at a certain interval along a transverse or longitudinal direction (e.g., a length direction), but are limited thereto. Alternatively, the first conductive portion 11 can have a plurality of hollow structures 112 (e.g., hollow holes or grooves as shown in FIG. 6).

The relevant technical details mentioned in the first and second embodiments are still valid in the present embodiment and will not be repeated here for the sake of brevity. Similarly, the technical details mentioned in the present embodiment can also be applied in the first and second embodiments.

[Beneficial Effects of the Embodiments]

In the vertical type multi-chip device of the present disclosure, by virtue of “the first functional chip is embedded in the intermediate layer and electrically connected to the base structure, and the second functional chip is disposed on the intermediate layer and configured to be electrically connected to the first functional chip via the first signal transmission path and to the base structure via the second signal transmission path,” a closer interconnection in a vertical direction between chips and between chips and a base structure can be achieved based on general process capability, and no wiring lines and through silicon vias are used in an entire structure. Furthermore, the vertical type multi-chip device of the present disclosure has the advantages of higher flexibility of use, a smaller volume, and a higher integration density.

More specifically, the vertical type multi-chip device of the present disclosure can further include a heat dissipating member disposed between the functional chips and the metal shielding layer and protected by the protective layer. Accordingly, the heat dissipation problem of an electronic product can be solved to ensure normal operation of the electronic product, thereby extending the lifespan of the electronic product.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A vertical type multi-chip device, comprising:
a base structure;
an intermediate layer disposed on the base structure and having a first signal transmission path and a second signal transmission path;
a first functional chip embedded in the intermediate layer and electrically connected to the base structure; and
a second functional chip disposed on the intermediate layer and configured to be electrically connected to the first functional chip via the first signal transmission path and to the base structure via the second signal transmission path.

2. The vertical type multi-chip device according to claim 1, wherein the intermediate layer has an inner side area and an outer side area, the inner side area has a first conductive structure arranged therein, and the outer side area has a second conductive structure arranged therein; wherein the first conductive structure is configured to provide the first signal transmission path, and the second conductive structure is configured to provide the second signal transmission path.

3. The vertical type multi-chip device according to claim 2, wherein the first conductive structure is a line redistribution structure, and the second conductive structure includes a plurality of conductive vias.

4. The vertical type multi-chip device according to claim 2, wherein the base structure includes a first conductive portion and a plurality of second conductive portions arranged adjacent to and at a periphery of the first conductive portion, the first functional chip is in electrical connection with both the first conductive portion and the second conductive portions, and the second functional chip is in electrical connection with the second conductive portions via the second signal transmission path of the intermediate layer.

5. The vertical type multi-chip device according to claim 4, wherein the first conductive portion is located in an orthogonal projection area of the first functional chip on the base structure, and the second conductive portions are arranged in a radial distribution around the first conductive portion and with the first conductive portion as a center.

6. The vertical type multi-chip device according to claim 5, wherein the base structure has a central area and a peripheral area outside the central area, the central area has a first conductive portion arranged therein, and the peripheral area has a plurality of second conductive portions arranged therein.

7. The vertical type multi-chip device according to claim 6, further comprising a plurality of supporting portions, each of which has a first end immovably fixed to the peripheral area and a second end connected to the first conductive portion.

8. The vertical type multi-chip device according to claim 7, wherein the first conductive portion is a single lead or multi-lead electrode, the second conductive portions are each a lead, and the supporting portions are each a connecting rod.

9. The vertical type multi-chip device according to claim 7, wherein the first conductive portion includes a plurality of conductive bodies separated from each other and immovably fixed to the second end of at least one of the supporting portions.

10. The vertical type multi-chip device according to claim 7, wherein the first conductive portion has a plurality of hollow structures.

11. The vertical type multi-chip device according to claim 9, wherein the peripheral area of the base structure has a plurality of corner positions, and the first ends of the supporting portions are respectively and immovably fixed to the corner positions.

12. The vertical type multi-chip device according to claim 1, further comprising a protective layer that isolates the intermediate layer, the first functional layer, and the second functional layer from an outside environment.

13. The vertical type multi-chip device according to claim 12, further comprising a metal shielding layer disposed on the protective layer.

14. The vertical type multi-chip device according to claim 13, wherein the protective layer has a lateral surface surrounding the intermediate layer, the first functional layer, and the second functional layer, and an upper surface perpendicular to and connected to the lateral surface, and the metal shielding layer covers the lateral surface and the upper surface.

15. The vertical type multi-chip device according to claim 14, further comprising a heat dissipating member that is disposed between the second functional chip and the metal shielding layer.
